(19) United States
(12) Patent Application Publication
(10) Pub. No.: US 2003/0146804 A1
(43) Pub. Date: Aug. 7, 2003

(54) DEVICE HAVING A CAPICATOR WITH ALTERABLE CAPACITANCE, IN PARTICULAR A HIGH-FREQUENCY MICROSWITCH

(76) Inventors: Roland Mueller-Fiedler, Leonberg (DE); Thomas Walter, Renningen (DE); Markus Ulm, Stuttgart (DE)

Correspondence Address: KENYON & KENYON, ONE BROADWAY, NEW YORK, NY, 10004, US

(21) Appl. No.: 10/220,683

(22) PCT Filed: Dec. 13, 2001
(86) PCT No.: PCT/DE01/04693

(30) Foreign Application Priority Data
Jan. 4, 2001 (DE) 101-00-296.3

(51) Int. Cl. H03H 7/38

(52) U.S. Cl. 333/33

(57) ABSTRACT

A device is described having a capacitor (200) with alterable capacitance C(U) for changing the impedance of a section of a coplanar waveguide, which may be used in particular as a high-frequency microswitch. A ground lead (110, 111) and a signal lead (120) interrupted by an electroconductive connection (121) which is self-supporting at least in some areas are provided, the capacitor (200) including the electroconductive connection (121) and an additional electroconductive connection (130) connected to the ground lead (110, 111). In addition a structure (150) connected to the electroconductive connection (121) is provided, which is designed in such a way that it reduces mechanical stresses which occur in the electroconductive connection (121). An additional embodiment of the device provides for the electroconductive connection (121) to be made of a material having coefficients of thermal expansion similar to that of silicon and a high modulus of elasticity compared to metals, in particular of molybdenum, tantalum or tungsten. Preferentially, the two embodiments are combined.

The present invention relates to a device, in particular one manufactured using micromechanics, having a capacitor with alterable capacitance for changing the impedance of a coplanar waveguide according to the definition of the species in the independent claims.

### BACKGROUND INFORMATION

In unpublished German Patent Application 100 37 385.2 a micromechanically manufactured high-frequency switch is described having a thin metal bridge which is inserted into the signal lead of a coplanar waveguide at a predefined length and interrupts it there. It was also proposed there that an electroconductive connection be provided beneath the metal bridge between two ground leads of the coplanar waveguide which are routed parallel to the signal lead, the surface of the connection beneath the bridge having a dielectric layer. The metal bridge thus forms, together with the electroconductive connection, a capacitor with which the impedance of the relevant section of the coplanar waveguide is alterable. When the high-frequency switch is operated, the bridge may then be drawn onto the dielectric layer, electrostatically or by applying an appropriate voltage to the capacitor, causing the capacitance of the plate capacitor made up of the bridge and the electroconductive connection to increase, which affects the propagation properties of the electromagnetic waves carried on the waveguide. In particular, in the “off” state, i.e., the metal bridge is down, a large part of the power is reflected, whereas in the “on” state, i.e., the metal bridge is up, a large part of the power is transmitted.

### ADVANTAGES OF THE INVENTION

The device according to the present invention having a capacitor with alterable capacitance has the advantage over the related art that temperature changes which arise during operation of the device do not result in temperature-dependent electromechanical properties of this device.

In particular, the provision of an additional structure—preferably U-shaped—and in particular the use of this structure for suspending the second connection on at least one side makes it possible to equalize “in-plane” stresses; that is, this structure has the advantageous effect that intrinsic and/or thermally induced stresses in the bridge formed by the second connection are largely eliminated. It is also advantageous that the restoring force in the event of an “out-of-plane” deflection of this bridge, i.e., a second connection of bending moments, is analogous to a thin bar clamped at one side, and that the “out-of-plane” flexural rigidity of the incorporated structure is negligible.

In addition it is also advantageous that the flexural rigidity of the bridge formed by the second connection is only slightly temperature-dependent over the temperature coefficient of the modulus of elasticity of the material of the bridge.

Since silicon is often used as a substrate material, which has a significantly lower coefficient of thermal expansion than most other metals which are used to implement the second connection because of their electrical conductivity, in micromechanics the use of molybdenum, tungsten, or tantalum as the material for the second electroconductive connection is advantageous.

Especially advantageous is the use of molybdenum, since it possesses a coefficient of thermal expansion of 4*10⁻⁶ per kelvin, which is similar to that of silicon at 2.7*10⁻⁶ kelvin, and since it exhibits a modulus of elasticity which at 340 GPa is relatively high compared to that of other metals, for example aluminum at 70 GPa.

When molybdenum, tantalum, or tungsten is used, temperature changes do not result in a build-up of stresses in the second connection, or only on a significantly lower scale, so that such temperature changes no longer cause unwanted impairment of the necessary switching voltage and the switching times which occur in the device. In addition, the reduction achieved in these stresses also influences the forces which occur to move the second connection when switching, in particular restoring forces.

The high modulus of elasticity of molybdenum, tantalum or tungsten also has the advantage that the bridge formed by the second connection has sufficient flexural rigidity.

Advantageous refinements of the present invention result from the measures named in the subclaims.

Thus it is advantageous when molybdenum, tantalum, or tungsten is used as the material for the second connection and at the same time as the material for the inserted structure.

Providing the additional structure has the further advantage that additional inductance is incorporated into the equivalent circuit diagram of the device according to the present invention by giving it a calculated shape and dimension, through which the insertion loss of this device may be reduced.

### DRAWING

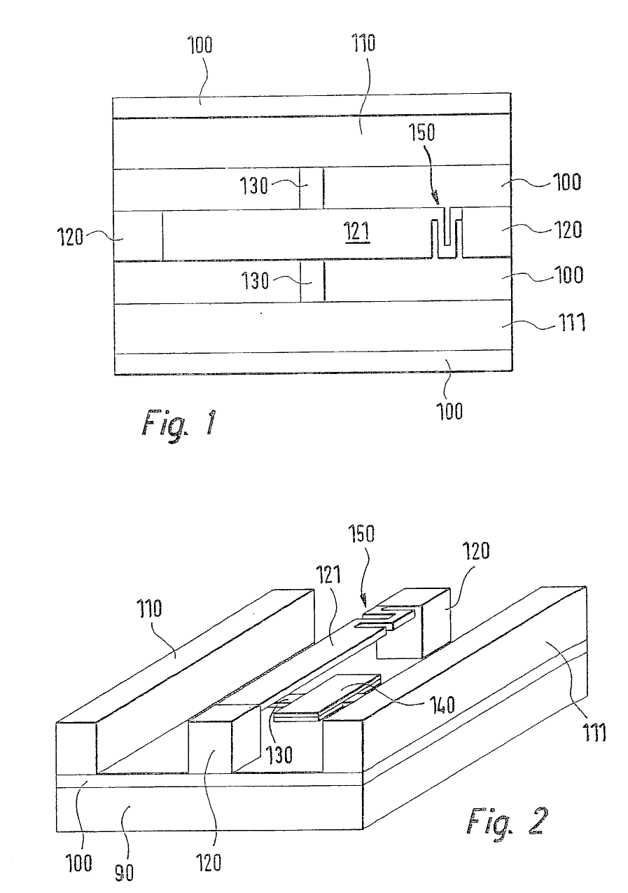

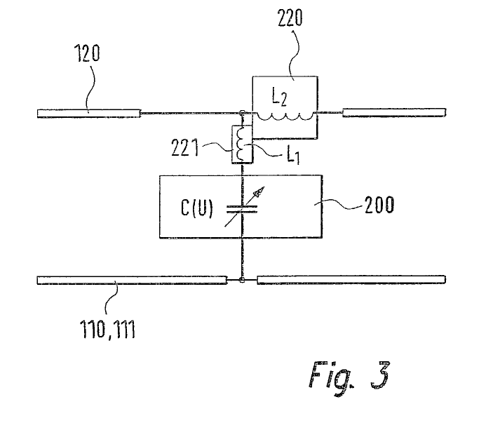

The present invention is explained in greater detail on the basis of the drawing and in the subsequent description. FIG. 1 shows a top view of a device according to the present invention, FIG. 2 shows a perspective view of FIG. 1, and FIG. 3 shows an equivalent circuit diagram of the device according to the present invention.

### DETAILED DESCRIPTION OF THE EXEMPLARY EMBODIMENT

FIG. 1 shows, as an exemplary embodiment, a micromechanically manufactured high-frequency short-circuit switch. Here, on a supporting body 90 of high-impedance silicon having a thickness for example of 100 μm to 500 μm an insulating layer 100 having a small loss angle is provided, made for example of silicon dioxide having a thickness of 100 mn to 3 μm, on which a coplanar waveguide is placed which has three coplanar electroconductive conductors which are routed, at least locally, essentially parallel to each other. The conductors of the coplanar waveguide are preferably made of metal and produced on the insulating layer 100 initially for example by sputtering on an initial metallization and via one or more subsequent galvanic process steps. The outer two of the three conductors of the coplanar waveguide correspond to a first ground lead 110 and a second ground lead 111, while the middle conductor corresponds to a signal lead 120 of the coplanar waveguide. FIG. 1 shows only the section of such a coplanar waveguide routed on the insulating layer 100 which is of interest for the device according to the present invention.

The two ground leads 110, 111 of the coplanar waveguide are linked by a first electroconductive connection 130, made for example of a metal, which is applied in some areas of the surface of insulating layer 100 and which has little “height” in comparison with the “height” of ground leads 110, 111. In this respect first connection 130 links ground leads 110, 111 at their “feet” on insulating layer 100 in the form of a short-circuiting link. In the area of first connection 130, signal lead 120 of the coplanar waveguide is also interrupted; that is, first connection 130 is not electroconductively connected to signal lead 120. In addition, a dielectric layer 140 which is not visible in FIG. 1 is applied to first connection 130 in the area of the interruption.

FIG. 1 also shows that interrupted signal lead 120 is provided with a second electroconductive connection 121 which is inserted between the ends of interrupted signal lead 120 in the form of a metal connecting bridge or signal bridge, and which runs at a certain clearance from the plane of insulating layer 100 and initially parallel thereto, the clearance from second connection 121 to insulating layer 100, i.e., to first connection 130, corresponding approximately to the height of signal lead 120. As a result, when no forces are present on second connection 121, second connection 121 “floats” between the ends of interrupted signal lead 120, at least largely self-supporting.

Second connection 121 is preferably made of molybdenum. However, other electroconductive materials having a coefficient of thermal expansion similar to that of silicon and a high modulus of elasticity compared to common metals such as aluminum are also suitable. Their typical dimensions are between 20 μm×150 μm and 100 μm×600 μm, with a thickness of 0.5 μm to 1.5 μm.

It is also recognizable in FIG. 1 that between second connection 121, which is preferably designed in the form of a flat strip, and signal line 120, a structure is provided, which is connected to both, and which is designed as a U-shaped or meander-shaped spring running flat in the plane of the strip of second connection 121. This structure 150 causes a reduction in mechanical stresses which occur in second connection 121, in particular under temperature fluctuations or are also intrinsically present.

According to FIG. 1 structure 150 also functions, at least on one side, as mounting and connection of self-supporting, electroconductive second connection 121 to an assigned section of signal lead 120. Structure 150 may be provided for that purpose at one end as shown, or alternatively at both ends of second connection 121. In addition it is also possible to insert structure 150 in some areas, for example centrally, in second connection 121.

Preferentially, second connection 121 and structure 150 are designed as a single piece; i.e., structure 150 is a structured part of second connection 121.

FIG. 2 shows the section of the device in FIG. 1 according to the present invention in perspective. Here dielectric layer 140 as well as first connection 130, which runs beneath dielectric layer 140 and electroconductively connects first ground lead 110 and second ground lead 111, are also visible.

FIG. 3 shows an equivalent circuit diagram of the device according to the present invention, with the two ground leads 110, 111 shown merely in the form of a single conductor of the coplanar waveguide, since they are at the same potential. In addition, signal lead 120 of the coplanar waveguide is shown in FIG. 3. A capacitor 200 (C(U)) is positioned between signal lead 120 and ground leads 110, 111. In addition, at this point a first inductance 221 (L¹) is present, which is implemented in FIGS. 1 and 2 essentially by first connection 130.

This first inductance 221 (L₁) may be defined by a structuring of first connection 130, which acts as a DC voltage short circuit between ground leads 110, 111. At the same time it may be determined in particular by a local variation of the length to width ratio of first connection 130 or its shape, for example in meander shape or similar.

Capacitor 200 in FIG. 3 is implemented at least partially by first connection 130 and second connection 121, while its capacitance is alterable by second connection 121 becoming mechanically deformed when an appropriate voltage, in particular a DC voltage U, is applied between signal lead 120 and ground leads 110, 111, so that it changes its clearance from first connection 130 at least in partial areas. In particular, when second connection 121 is in its non-deformed state, i.e., when no DC voltage U is applied or in the “on” state, capacitor 200 exhibits a capacitance Cₒₙ, and with the DC voltage U applied and an associated deflection of the second connection from the rest position in the direction of dielectric layer 140, i.e., in the “off” state, it exhibits a capacitance C_{off}.

The provided structure 150 in the form of a U-shaped spring continues to act likewise through the associated current path confinement and current path extension as second inductance 220 (L₂) connected in series, which causes additional reflections, especially at high frequencies. In the equivalent circuit diagram according to FIG. 3, second inductance 220 produces a reduction in the insertion loss of the device, which is determined in particular by the reflection at capacitance Cₒₙ. In this respect this capacitance Cₒₙ is able to be equalized by the inductance L₂, which in turn is given or may be set particularly easily through appropriate dimensioning and structuring of structure 150. Preferentially, inductance L₂ is set so that at the particular operating frequency this formula applies for impedance Z_{L} of signal lead 120:

$${Z}_{L} = \sqrt{\frac{{L}_{2}}{{C}_{on}}}$$

In addition, through appropriate dimensioning and shaping of the DC voltage short circuit, i.e., first connection 130, first inductance 221 (L₁) which is arranged in series with formed plate capacitor 200 may be adjusted to the particular operating frequency of the device according to the present invention such that a series resonant circuit results, whose resonant frequency Vᵣₑₛ, when second connection 121 is switched off, is near the operating frequency of the device:

$${v}_{res} = \frac{1}{2 π} \sqrt{{L}_{1} {C}_{off}}$$

In the “on” state, that is, in the state in which second connection or bridge 121 is up with relatively great clearance from insulating layer 100, the device is then operated due to the reduced capacitance of plate capacitor 200 outside of this resonant frequency in such a way that a higher insertion loss does not result. Incidentally, the operating frequencies of the explained device for applications in the field of ACC (adaptive cruise control) or SRR (short range radar) are 77 GHz or 24 GHz.

FIGS. 1 and 2 show mechanically deformable second connection 121, for the event that the depicted section of the coplanar waveguide has a high coefficient of transmission and a low coefficient of reflection. The clearance of first connection 130 and second connection 121, which along with dielectric layer 140 definitively determines the capacitance C(U) of capacitor 200, is at a maximum in FIG. 2; it is around 2 μm to 4 μm. In the event that a DC voltage U is applied between first connection 130 and second connection 121, an electrostatic attracting force occurs between first connection 130 and second connection 121, with the result that second connection 121 is deformed, and at least in a partial area, namely essentially in the middle of the metal bridge, is drawn to first connection 130, i.e., to dielectric layer 140 which is applied to first connection 130, the dielectric layer being made up for instance of silicon dioxide or silicon nitride.

Regarding further details of the explained device and its functionality, reference is made to German Patent Application 100 37 385.2.

What is claimed is:

1. A device having a capacitor with alterable capacitance for changing the impedance of a section of a coplanar waveguide, in particular a high-frequency microswitch, having a ground lead (110, 111) and a signal lead (120) interrupted by an electroconductive connection (121) which is self-supporting at least in some areas, the capacitor (200) at least partially including the electroconductive connection (121) and an additional electroconductive connection (130) which is connected to the ground lead (110, 111),
wherein at least one structure (150) connected to the electroconductive connection (121) is provided, which is designed in such a way that it reduces mechanical stresses which occur in the electroconductive connection (121).

2. The device according to claim 1,
wherein the structure (150) connects the electroconductive connection (121) in the form of a mounting to a section of the signal lead (120).

3. The device according to claim 1 or 2,
wherein the structure (150) is inserted in some areas into the electroconductive connection (121) or the electroconductive connection (121) is structured in some areas to form the structure (150), the structure (150) in particular forming a mounting of the electroconductive connection (121).

4. The device according to one of the preceding claims,
wherein the electroconductive connection (121) is designed at least in some areas in the form of a strip and the structure (150) as a U-shaped or meander-shaped spring, in particular as a U-shaped or meander-shaped spring running flat in the plane of the strip.

5. The device according to one of the preceding claims,
wherein the structure (150) is designed in such a way that it reduces or suppresses intrinsic mechanical stresses and/or those which occur due to temperature fluctuations in the electroconductive connection (121), in particular such stresses which are directed parallel to the plane of the structure (150).

6. The device according to one of the preceding claims,
wherein the signal lead (120) of the waveguide is interrupted at a predetermined length by the electroconductive connection (121) and the structure (150); and the additional electroconductive connection (130) connects two ground leads (110, 111) of the waveguide which run parallel to the signal lead (120) in the area defined by the predetermined length.

7. The device according to one of the preceding claims,
wherein the structure (150) and/or the electroconductive connection (121) is made of a material having coefficients of thermal expansion similar to that of silicon and a high modulus of elasticity compared to metals, in particular of molybdenum, tantalum or tungsten.

8. The device according to one of the preceding claims,
wherein the change in the capacitance (C) of the capacitor (200) may be effected by an electrostatic force between the electroconductive connection (121) and the additional electroconductive connection (130).

9. The device according to one of the preceding claims,
wherein the additional electroconductive connection (130) forms a first inductance (221) in series with the capacitor (200).

10. A device having a capacitor with alterable capacitance for changing the impedance of a section of a coplanar waveguide, in particular a high-frequency microswitch, having a ground lead (110, 111) and a signal lead (120) interrupted by an electroconductive connection (121) which is self-supporting at least in some areas, the capacitor (200) at least partially including the electroconductive connection (121) and an additional electroconductive connection (130) which is connected to the ground lead (110, 111),
wherein the electroconductive connection (121) is made of a material having coefficients of thermal expansion similar to that of silicon and a high modulus of elasticity compared to metals, in particular of molybdenum, tantalum or tungsten.

11. The device according to claim 10,
wherein a structure (150) is provided, which is connected to the electroconductive connection (121), that is designed in such a way that it reduces mechanical stresses which occur in the electroconductive connection (121).
